(19) United States
(12) Patent Application Publication
(10) Pub. No.: US 2006/0017516 A1
(43) Pub. Date: Jan. 26, 2006

(54) Small crystal with grounded package

(75) Inventor: William B. Higgins, Silverado, CA (US)

Correspondence Address: STERNE, KESSLER, GOLDSTEIN & FOX PLLC, 1100 NEW YORK AVENUE, N.W., WASHINGTON, DC, 20005, US

(73) Assignee: Broadcom Corporation, Irvine, CA (US)

(21) Appl. No.: 11/136,602

(22) Filed: May 25, 2005

Related U.S. Application Data
(60) Provisional application No. 60/573,835, filed on May 25, 2004.

(51) Int. Cl. H03B 5/36; H03B 5/32

(52) U.S. Cl. 331/158; 331/116 R

(57) ABSTRACT

A small crystal oscillator with metal packaging includes a small size crystal oscillator circuit, a body encompassing the small size crystal oscillator circuit, first and second terminal leads coupled to the crystal oscillator circuit through the body, metal packaging encompassing at least a portion of the body, and a ground connection electrically coupled to the metal packaging. The invention includes a variety of shapes and configurations for the metal packaging and a variety of pin configurations.

### CROSS-REFERENCE TO RELATED APPLICATIONS

This application claims priority to U.S. Provisional Application No. 60/573,835, filed May 25, 2004, entitled “Small Crystal With Grounded Package,” which is incorporated herein by reference in its entirety.

### BACKGROUND OF THE INVENTION

1. Field of the Invention

The invention relates generally to crystal oscillators and, more particularly, to relatively small size crystal oscillators with metal packaging.

2. Related Art

Conventional crystal oscillators include relatively large crystal oscillators, commonly referred to as HC-49U crystal oscillators (hereafter, “large crystals”), and relatively small crystal oscillators, commonly referred to as HC-49US crystal oscillators (hereafter, “small crystals”). Large crystal oscillators are available in ceramic or metal packaging. The metal packaging can be grounded to protect surrounding components from electromagnetic interference (“EMI”) from the crystal. The grounded metal packaging also protects the crystal from externally generated EMI.

Small crystal oscillators occupy less physical space and generally have a smaller footprint than large crystal oscillators. Conventional small crystal oscillators are presently available only in ceramic packaging, not metal packaging.

Crystal oscillator circuits utilized in small crystal oscillators are physically different than crystal oscillator circuits utilized in large crystal oscillators. As a result, the physical size of a crystal oscillator package is a function of the type of crystal utilized within. The physical size of a crystal oscillator package is, therefore, not simply a manufacturing or design choice.

What is needed, therefore, are relatively small crystal oscillators with metal packaging.

### SUMMARY OF THE INVENTION

The present invention is directed to relatively small crystal oscillators with metal packaging. The invention includes a variety of shapes and configurations for the metal packaging and a variety of pin configurations.

A small crystal oscillator in accordance with one embodiment of the present invention includes a small size crystal oscillator circuit, a body encompassing the small size crystal oscillator circuit, first and second terminal leads coupled to the crystal oscillator circuit through the body, metal packaging encompassing at least a portion of the body, and a ground connection electrically coupled to the metal packaging.

Additional features and advantages of the invention will be set forth in the description that follows. Yet further features and advantages will be apparent to a person skilled in the art based on the description set forth herein or may be learned by practice of the invention. The advantages of the invention will be realized and attained by the structure particularly pointed out in the written description and claims hereof as well as the appended drawings.

It is to be understood that both the foregoing summary and the following detailed description are exemplary and explanatory and are intended to provide further explanation of the invention as claimed.

### BRIEF DESCRIPTION OF THE DRAWINGS/FIGURES

The present invention will be described with reference to the accompanying drawings, wherein like reference numbers indicate identical or functionally similar elements. In the drawings:

FIG. 1A is a top plan view of an exemplary large crystal oscillator and an exemplary small crystal oscillator.

FIG. 1B is a side view of the small crystal oscillator, taken along the line A illustrated in FIG. 1A.

FIG. 1C is a side view of the small crystal oscillator, taken along the line B illustrated in FIG. 1A.

FIG. 2A is a cut-away top plan view of the small crystal oscillator, wherein the metal packaging encompasses an upper portion of the body.

FIG. 2B is a side view of the small crystal oscillator, taken along the line A illustrated in FIG. 2A.

FIG. 2C is a side view of the small crystal oscillator, taken along the line B illustrated in FIG. 2A.

FIG. 3A is a top plan view of the small crystal oscillator, including a ribbon-type ground terminal.

FIG. 3B is a side view of the small crystal oscillator, taken along the line A illustrated in FIG. 3A.

FIG. 3C is a side view of the small crystal oscillator, taken along the line B illustrated in FIG. 3A.

### DETAILED DESCRIPTION OF THE INVENTION

The present invention is directed to relatively small crystal oscillators with metal packaging. The invention includes a variety of shapes and configurations for the metal packaging and a variety of pin configurations.

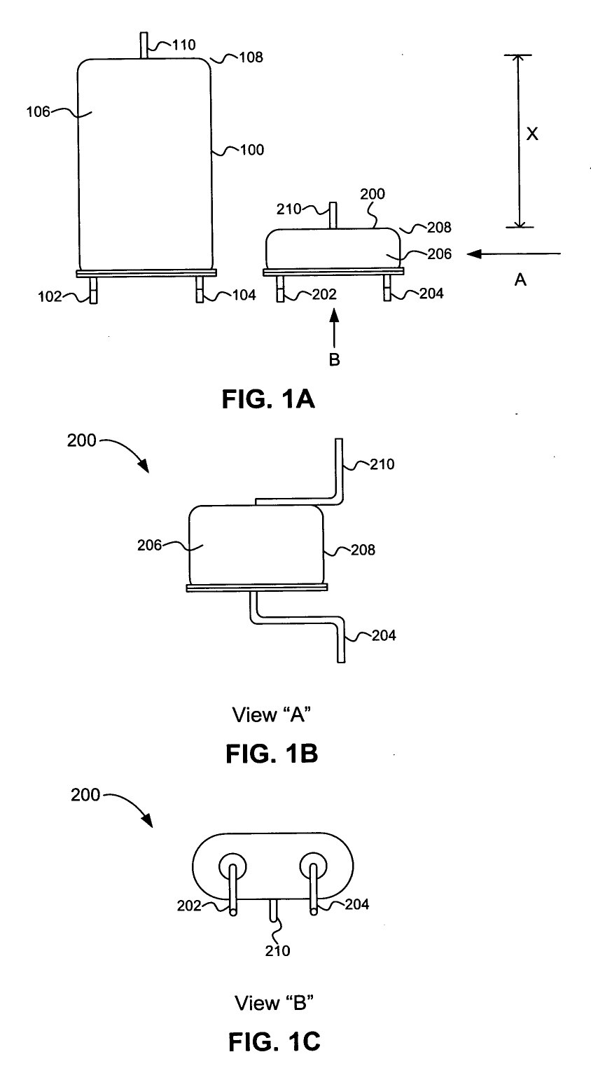

FIG. 1A is a top plan view of an exemplary large crystal oscillator 100 and an exemplary small crystal oscillator 200. The large crystal oscillator 100 includes a body 106, enclosing a large crystal oscillator circuit. The large crystal oscillator 100 further includes terminal leads 102 and 104, a metal package 108, and a ground lead 110 protruding therefrom.

The small crystal oscillator 200 includes a body 206, enclosing a small crystal oscillator circuit. The small crystal oscillator 200 further includes terminal leads 202 and 204, a metal package 208, and a ground lead 210 protruding therefrom.

In the example of FIG. 1, the large crystal oscillator 100 is a distance “x” longer or taller than small crystal oscillator 200. The distance x is illustrated for exemplary purposes. In practice, the distance x is relative. Large and small crystal oscillators are distinguished from one another primarily by the type of crystal oscillator circuit within, as is known to those skilled in the art.

With respect to the small crystal oscillator 200, the metal packaging 208 is coupled to ground through ground lead 210. The metal packaging 208 protects surrounding components from electromagnetic interference (“EMI”) generated by the small crystal oscillator circuit within the body 206. The grounded metal packaging 208 also protects the small crystal oscillator circuit from externally generated EMI.

The small crystal oscillator 200 can have, for example, and without limitation, a round cylindrical shape, an oval-cylindrical shape, or any of a variety of other shapes. For example, FIG. 1B is a side plan view of the small crystal oscillator 200, taken along the line A illustrated in FIG. 1A. FIG. 1C is a side view of the small crystal oscillator 200, taken along the line B illustrated in FIG. 1A. In the examples of FIGS. 1A-1C, the small crystal oscillator 200 has an oval-cylindrical shape.

The metal package 208 can encompass the entire body 206, or portions thereof. Covering portions of the body 206 with the metal packaging 208, rather than covering the entire body 206, can be utilized, for example, to reduce the quantity of metal needed, and/or to obtain desired EMI blocking characteristics.

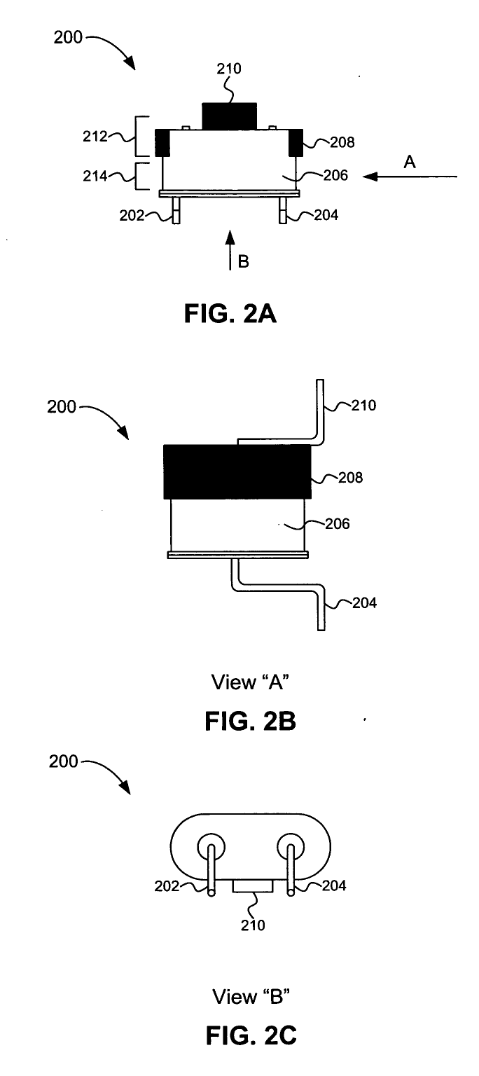

For example, FIG. 2A is a cut-away top plan view of the small crystal oscillator 200, wherein the metal packaging 208 encompasses an upper portion 212 of the body 206. FIG. 2B is a side view of the small crystal oscillator 200 illustrated in FIG. 2A. Alternatively, the metal packaging 208 can be manufactured to encompass a lower portion 214 of the body 206, and/or one or more side portions of the body 206.

The location of the terminal leads 202 and 204, and the ground lead 210, relative to one another and relative to the body 206, is variable. In the example of FIGS. 1A-1C, and 2A-2C, the terminal leads 202 and 204 extend from a first end of the small crystal oscillator 200, and the ground lead 210 extends from a second end of the small crystal oscillator 200, which is opposite from the first end. The invention is not, however, limited to this configuration.

The ground terminal 210 can be formed in any of a variety of shapes.

For example, and without limitation, the ground terminal 210 can be fabricated as a wire-type terminal, as illustrated in FIGS. 1A-1C, or as a ribbon-type terminal, as illustrated in FIGS. 2A-2C.

The terminal leads 202 and 204, and the ground terminal 210 can be designed for surface mounting or “through-the-hole” mounting on a circuit board.

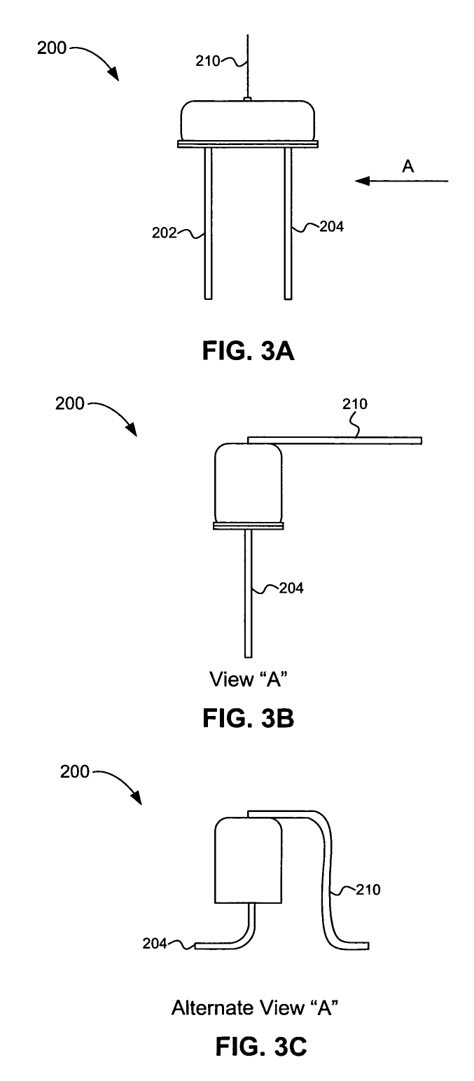

The terminal leads 202 and 204, and the ground terminal 210 can be shaped so that the small crystal oscillator 200 is mounted in a lay-down position, as illustrated in FIGS. 1A-1C, and 2A-2C, or in an upright position, as illustrated in FIGS. 3A-3C.

FIG. 3B is a side view of the small crystal oscillator, taken along the line A illustrated in FIG. 3A. FIG. 3C is a side view of the small crystal oscillator, taken along the line B illustrated in FIG. 3A.

### CONCLUSION

The present invention has been described above with the aid of functional building blocks illustrating the performance of specified functions and relationships thereof. The boundaries of these functional building blocks have been arbitrarily defined herein for the convenience of the description. Alternate boundaries can be defined so long as the specified functions and relationships thereof are appropriately performed. Any such alternate boundaries are thus within the scope and spirit of the claimed invention. One skilled in the art will recognize that these functional building blocks can be implemented by discrete components, application specific integrated circuits, processors executing appropriate software and the like and combinations thereof.

While various embodiments of the present invention have been described above, it should be understood that they have been presented by way of example only, and not limitation. Thus, the breadth and scope of the present invention should not be limited by any of the above-described exemplary embodiments, but should be defined only in accordance with the following claims and their equivalents.

What is claimed is:

1. A small crystal oscillator with metal packaging, comprising:
a small size crystal oscillator circuit;
a body encompassing the small size crystal oscillator circuit;
first and second terminal leads extending outwardly from the body and coupled to the crystal oscillator circuit through the body;
metal packaging encompassing at least a portion of the body; and
a ground connection electrically coupled to the metal packaging.

2. The small crystal oscillator of claim 1, wherein the metal packaging encompasses substantially the entire body.

3. The small crystal oscillator of claim 1, wherein the metal packaging encompasses less than the entire body.

4. The small crystal oscillator of claim 1, wherein the metal packaging encompasses an upper portion of the body.

5. The small crystal oscillator of claim 1, wherein the metal packaging encompasses a lower portion of the body.

6. The small crystal oscillator of claim 1, wherein the metal packaging encompasses a side portion of the body.

7. The small crystal oscillator of claim 1, wherein the first and second terminal leads protrude from a first end of the body and the ground terminal protrudes from a second end of the body, wherein the first and second ends of the body are disposed opposite one another.

8. The small crystal oscillator of claim 1, wherein the ground terminal comprises a wire-type terminal.

9. The small crystal oscillator of claim 1, wherein the ground terminal comprises a ribbon-type terminal.

10. The small crystal oscillator of claim 1, wherein the first and second terminal leads and the ground terminal are configured for upright mounting.

11. The small crystal oscillator of claim 1, wherein the first and second terminal leads and the ground terminal are configured for lay-down mounting.
